(19) United States
(12) Patent Application Publication
(10) Pub. No.: US 2026/0190424 A1
(43) Pub. Date: Jul. 2, 2026

(54) SELF-ALIGNED BACKSIDE CONTACTS MADE USING DIELECTRIC PLUGS

(71) Applicant: Intel Corporation, Santa Clara, CA (US)

(72) Inventors: Nikhil J. Mehta, Portland, OR (US); Umang Desai, Portland, OR (US); Atul Madhavan, Portland, OR (US); Mark Koeper, Portland, OR (US); Nicholas J. Kybert, Portland, OR (US); Shu Zhou, Portland, OR (US)

(73) Assignee: Intel Corporation, Santa Clara, CA (US)

(21) Appl. No.: 19/002,924

(22) Filed: Dec. 27, 2024

(51) Int. Cl. H10D 64/23; H10D 62/10; H10D 84/01; H10D 84/83

(52) U.S. Cl. CPC H10D 64/258; H10D 62/116; H10D 84/832; H10D 84/0151

(57) ABSTRACT

Techniques are provided to form an integrated circuit having self-aligned backside contacts. The process includes frontside operations to provide dielectric plugs beneath source or drain regions that can be selectively removed from the backside of the structure. A FET (field effect transistor) includes semiconductor material extending in a first direction between source and drain regions, and a gate structure extending in a second direction around the semiconductor material. During the formation of inner dielectric spacers between the semiconductor material, some of the dielectric material remains at the bottom of source/drain trenches to form dielectric plugs that are self-aligned beneath the source or drain regions. These self-aligned dielectric plugs can be exposed from the backside following the removal of the substrate and replaced with backside conductive contacts that are self-aligned beneath the source or drain regions. A dielectric liner may also be provided over the dielectric plugs.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Due to the small size of the transistor elements, such as the transistor gate, source, or drain, it can be difficult to provide effective contacts while maintaining desired operation speeds and power requirements. Accordingly, there remain a number of non-trivial challenges with respect to forming such high-density semiconductor devices.

### BRIEF DESCRIPTION OF THE DRAWINGS

FIG. 1 is a cross-sectional view of different semiconductor devices in an integrated circuit that have self-aligned backside contacts, in accordance with an embodiment of the present disclosure.

FIGS. 2A-2N are cross-sectional views that illustrate different stages in an example process for forming an integrated circuit having self-aligned backside contacts, in accordance with some embodiments of the present disclosure.

FIG. 2N′ is another cross-sectional view of the integrated circuit having the self-aligned backside contacts that further extend into the source or drain regions, in accordance with an embodiment of the present disclosure.

FIG. 3 illustrates a cross-sectional view of a chip package containing one or more semiconductor dies, in accordance with some embodiments of the present disclosure.

FIG. 4 is a flowchart of a fabrication process for semiconductor devices having self-aligned backside contacts, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having self-aligned backside contacts. The techniques can be used in any number of integrated circuit applications and are particularly useful with respect to logic and memory cells, such as those cells that use finFETs or gate-all-around transistors (e.g., ribbonFETs and nanowire FETs) or forksheet transistors. The process includes frontside operations to provide dielectric plugs beneath source or drain regions that can be selectively removed from the backside of the structure. In one example, a number of FETs (field effect transistors) each includes semiconductor material extending in a first direction between source and drain regions, and gate structures extending in a second direction around the semiconductor material of a given FET. The semiconductor material of each FET may include any number of nanowires (or nanoribbons or nanosheets, as the case may be). During the formation of inner dielectric spacers between the semiconductor material, some of the dielectric material remains at the bottom of source/drain trenches to form dielectric plugs that are self-aligned beneath the source or drain regions. These self-aligned dielectric plugs can be exposed from the backside following the removal of the substrate and selectively removed to form backside cavities that are self-aligned beneath the source or drain regions. One or more conductive materials are formed within the backside cavities to yield the self-aligned backside contacts. A dielectric liner may also be provided over the dielectric plugs after exposing the plugs from the backside of the structure. Numerous variations and embodiments will be apparent in light of this disclosure.

### General Overview

As previously noted above, there remain a number of non-trivial challenges with respect to integrated circuit fabrication. In more detail, backside interconnects have become increasingly more popular to route power and ground rails beneath the source or drain regions of various transistors. However, making effective connections between the backside interconnects and the source or drain regions is challenging. It is difficult to align the backside contacts beneath the source or drain regions using conventional lithography techniques. Misalignment of the contacts can result in no connection being made, or connection being made to the wrong element (e.g., an adjacent gate structure).

Thus, and in accordance with an embodiment of the present disclosure, techniques are provided herein to form self-aligned backside conductive contacts. According to some embodiments, a sacrificial plug is formed beneath a given source or drain region and is exposed from the backside of the structure following the removal of the substrate. The sacrificial plug may include a dielectric material that is deposited during a frontside process to form inner spacers between semiconductor regions (e.g., between adjacent nanoribbons or nanowires). Once the sacrificial plug has been exposed from the backside, a dielectric liner may be deposited on the backside of the structure and over any exposed surfaces of the sacrificial plug. After backfilling the device with a base dielectric structure, a bottom surface of the combined sacrificial plug/dielectric liner structure may be exposed via a polishing process. The combined sacrificial plug/dielectric liner structure may then be selectively etched away to reveal a bottom surface of the source or drain region within a backside cavity. One or more conductive materials may then be formed within the backside cavity to form a self-aligned backside contact. The dielectric liner may be included to widen the resulting backside cavity, making the process of forming the backside contact simpler. Furthermore, in some embodiments, the wider backside cavity makes it easier to perform directional etching through the exposed bottom surface of the source or drain region to drive the backside contact deeper into the source or drain region. The combined sacrificial plug/dielectric liner structure may remain beneath one or more source or drain regions that do not have backside contacts.

According to an embodiment, an integrated circuit includes a semiconductor device having a semiconductor region extending in a first direction from a first source or drain region to a second source or drain region and a gate structure extending in a second direction over the semiconductor region, a dielectric layer beneath the gate structure, a backside conductive contact extending through the dielectric layer and contacting a bottom surface of the first source or drain region, and a dielectric structure extending through the dielectric layer and contacting a bottom surface of the second source or drain region. The dielectric structure includes a dielectric cap and a dielectric liner on an outer surface of the dielectric cap.

According to another embodiment, a method of forming an integrated circuit includes: forming a fin comprising semiconductor material, the fin extending above a substrate; forming a dielectric layer adjacent to a subfin of the fin; forming a sacrificial gate and spacer structures over the fin; removing portions of the fin not covered by the sacrificial gates and spacer structures; removing a portion of the subfin to form a subfin recess; forming a first dielectric material within the subfin recess; forming a source or drain region at exposed ends of the semiconductor material above the first dielectric material; removing the subfin to yield a cavity adjacent to a bottom portion of the source or drain region; forming a dielectric liner on the exposed surfaces of the first dielectric material; forming a second dielectric material within the cavity and over the dielectric liner; polishing a backside surface of the second dielectric material to expose a bottom surface of the first dielectric material; removing at least the first dielectric material from the backside to expose a bottom surface of the source or drain region; and forming a conductive contact on the exposed bottom surface of the source or drain region.

According to another embodiment, an integrated circuit includes a first semiconductor device having a first semiconductor region extending in a first direction from a first source or drain region to a second source or drain region and a first gate structure extending in a second direction over the first semiconductor region, a second semiconductor device having a second semiconductor region extending in the first direction from a third source or drain region to a fourth source or drain region and a second gate structure extending in the second direction over the second semiconductor region, a dielectric layer beneath the first gate structure and the second gate structure, a conductive contact extending through the dielectric layer and contacting a bottom surface of the first source or drain region, and a dielectric structure extending through the dielectric layer and contacting a bottom surface of the third source or drain region. The dielectric structure includes a dielectric fill and a dielectric liner on an outer surface of the dielectric fill.

The techniques can be used with any type of planar or non-planar transistors, including finFETs (sometimes called double-gate transistors, or tri-gate transistors), or nanowire and nanoribbon transistors (sometimes called gate-all-around transistors), or forksheet transistors, to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide, indium phosphide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of self-aligned backside contacts (e.g., center of contact is aligned within 1 nm of the center of the source or drain region). In some embodiments, other source or drain regions can be observed that have a backside dielectric structure contacting the bottom surface of the other source or drain regions, where the dielectric structure includes a dielectric fill and a dielectric liner on the dielectric fill.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different material or chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

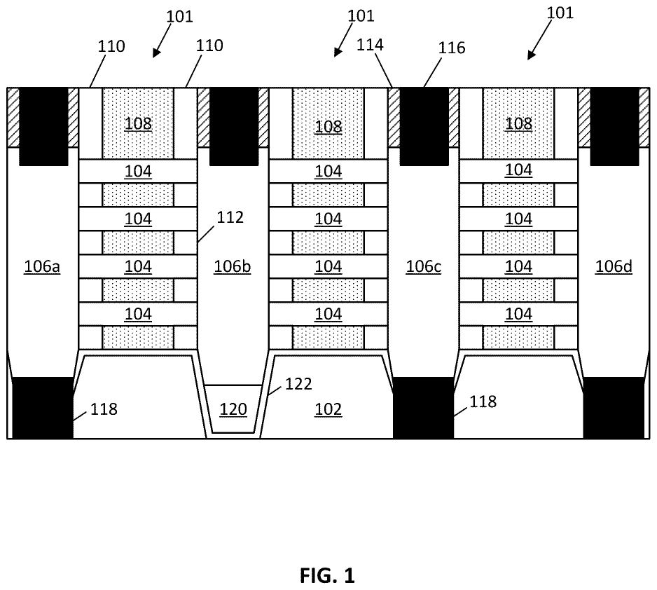

FIG. 1 is a cross-section view taken through semiconductor devices 101 along a ‘fin’ direction that illustrates the semiconductor bodies extending between source or drain regions of each of the semiconductor devices, in accordance with an embodiment of the present disclosure. Each of the semiconductor devices may be, for instance, non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions). Other examples may have a forksheet structure having a p-type device and an n-type device separated by a dielectric spine or structure. Any of semiconductor devices 101 may be p-channel devices (e.g., PMOS) or n-channel devices (e.g., NMOS).

The semiconductor material used in each of the semiconductor devices may be formed from or on a semiconductor substrate. According to some embodiments, the substrate is removed following the completion of all topside processing and is replaced with a base dielectric structure 102. Base dielectric structure 102 may represent any number of dielectric layers and/or materials. In some examples, base dielectric structure 102 includes one or more layers of silicon dioxide.

The one or more semiconductor regions of the devices may include fins that can be, for example, native to the substrate (formed from the substrate itself), such as silicon fins etched from a bulk silicon substrate. Alternatively, the fins can be formed of material deposited onto the substrate. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

Semiconductor devices 101 include one or more semiconductor regions (also called channel regions), such as one or more nanoribbons 104 extending between epitaxial source or drain regions 106a-106d (collectively referred to as source or drain regions 106) in the first direction. For example, the leftmost semiconductor device 101 includes nanoribbons 104 that extend between a first source or drain region 106a and a second source or drain region 106b and the rightmost semiconductor device 101 includes nanoribbons 104 that extend between a third source or drain region 106c and a fourth source or drain region 106d. In the illustrated example, a middle semiconductor device 101 includes nanoribbons 104 that extend between second source or drain region 106b and third source or drain region 106c.

Any of source or drain regions 106 may act as either a source region or a drain region, depending on the application and dopant profile. Any semiconductor materials suitable for source and drain regions can be used (e.g., group IV and group III-V semiconductor materials) for any of the illustrated source or drains regions 106. In any such cases, the composition and doping of source or drain regions 106 may be the same or different, depending on the polarity of the transistors. In an example, p-channel devices have a high concentration of p-type dopants in the associated source or drain regions 106, and n-channel devices have a high concentration of n-type dopants in the associated source or drain regions 106. Example p-type dopants include boron and example n-type dopants include phosphorous or arsenic. Any number of source and drain configurations and materials can be used. In some examples, p-type source or drain regions 106 include silicon germanium doped with boron and n-type source or drain regions 106 include silicon doped with phosphorous.

A gate structure 108 extends over nanoribbons 104 of each semiconductor device 101 in a second direction (e.g., into and out of the page) to form the transistor gate of each corresponding semiconductor device 101. The gate structure 108 may include a gate electrode that is made up of a conductive fill and one or more metal workfunction layers, according to some embodiments. Gate structure 108 also includes a gate dielectric that may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. In some embodiments, p-channel devices have a gate structure 108 with one or more workfunction layers of molybdenum nitride (MoN). Other metal workfunction layers of p-channel devices can include tantalum nitride (TaN) and titanium nitride (TiN). In some embodiments, n-channel devices have a gate structure 108 with one or more workfunction layers of tungsten. Other metal workfunction layers of n-channel devices can include tantalum nitride (TaN).

The gate dielectric of each gate structure 108 may include any suitable gate dielectric material(s). In some embodiments, the gate dielectric includes a layer of native oxide material (e.g., silicon dioxide germanium dioxide, or SiGe oxide) on nanoribbons 104, and a layer of high-k dielectric material (e.g., hafnium oxide or aluminum oxide) on the native oxide. According to some embodiments, spacer structures 110 and inner spacers 112 are present along the sidewalls of gate structures 108. Spacer structures 110 and inner spacers 112 may be any suitable dielectric material, such as silicon nitride, and provide separation between a given gate structure 108 and the adjacent source or drain region 106. Inner spacers 112 may separate adjacent nanoribbons 104 from one another along a third direction (e.g., a vertical direction).

According to some embodiments, a dielectric fill 114 may be present over the source or drain regions 106 within the corresponding source/drain trenches of semiconductor devices 101. A top surface of dielectric fill 114 may be substantially co-planar with a top surface of spacer structures 110. Dielectric fill 114 may include any suitable dielectric material, such as silicon dioxide, in some examples.

According to some embodiments, frontside contacts 116 are provided through dielectric fill 114 and contacting a top portion of source or drain regions 106. Frontside contacts 116 can include any suitable conductive material, such as tungsten, molybdenum, ruthenium, cobalt, or other metals. Frontside contacts 116 may be formed during the same metal deposition process(es) such that they all include the same conductive material.

According to some embodiments, backside contacts 118 are provided beneath any number of source or drain regions 106. In the illustrated example, backside contacts 118 contact the bottom surfaces of first source or drain region 106a, third source or drain region 106c, and fourth source or drain region 106d. Due to the fabrication process of these backside contacts 118, as will be discussed in more detail herein, each of backside contacts 118 is self-aligned with its corresponding source or drain region 106. For example, a center of backside contact 118 along both the first and second directions will have no appreciable offset, or be within 1 nm offset, from a center along both the first and second directions of the contacted source or drain region 106. In some embodiments, backside contacts 118 extend partially into their corresponding source or drain regions 106 to provide an enhanced ohmic contact between source or drain regions 106 and backside contacts 118.

According to some embodiments, one or more source or drain regions 106 do not have a backside contact. In the illustrated example, second source or drain region 106b has a dielectric structure on its bottom surface that includes a dielectric cap 120 and a dielectric liner 122 on the outside surface of dielectric cap 120. The dielectric structure extends through at least a portion of base dielectric structure 102 to contact the bottom surface of second source or drain region 106b. Dielectric cap 120 may directly contact the bottommost surface of second source or drain region 106b and may include any suitable dielectric material having sufficient etch selectivity to the dielectric material of base dielectric structure 102. Example materials for dielectric cap 120 include silicon nitride or silicon oxynitride.

According to some embodiments, dielectric liner 122 is on at least sidewall surfaces of dielectric cap 120 and may also be on the sidewall surfaces of a bottom portion of second source or drain region 106b. In some embodiments, dielectric liner 122 continues beneath the bottom of gate structures 108 and may also be on the sidewall surfaces of a bottom portion of other source or drain regions (e.g., 106a, 106c, and 106d) that do have backside contacts 118. Dielectric liner 122 may, for example, have a thickness between about 2 nm and about 7 nm and can include any suitable dielectric material having sufficient etch selectivity to the dielectric material of base dielectric structure 102. In some examples, dielectric liner 122 has the same material composition as dielectric cap 120. Example materials for dielectric liner 122 include silicon nitride or silicon oxynitride.

### Fabrication Methodology

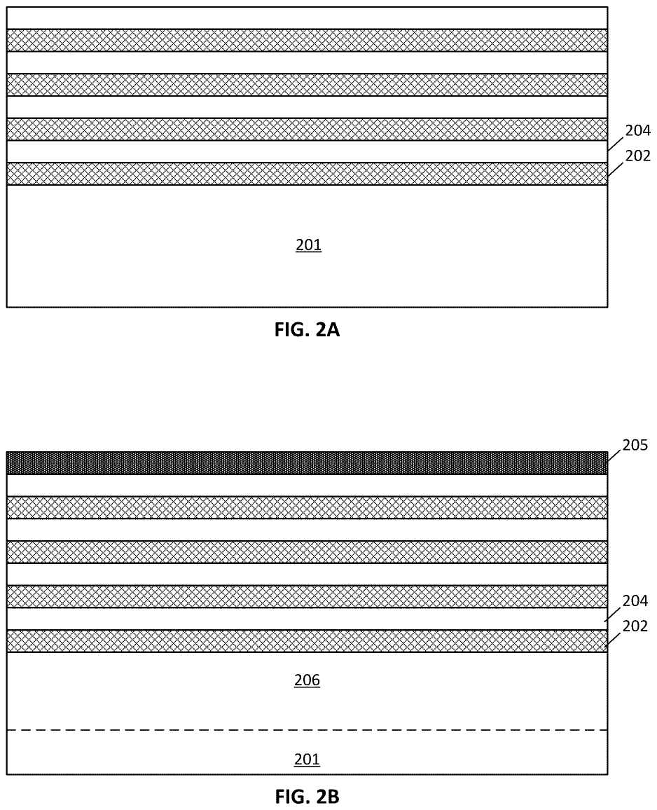

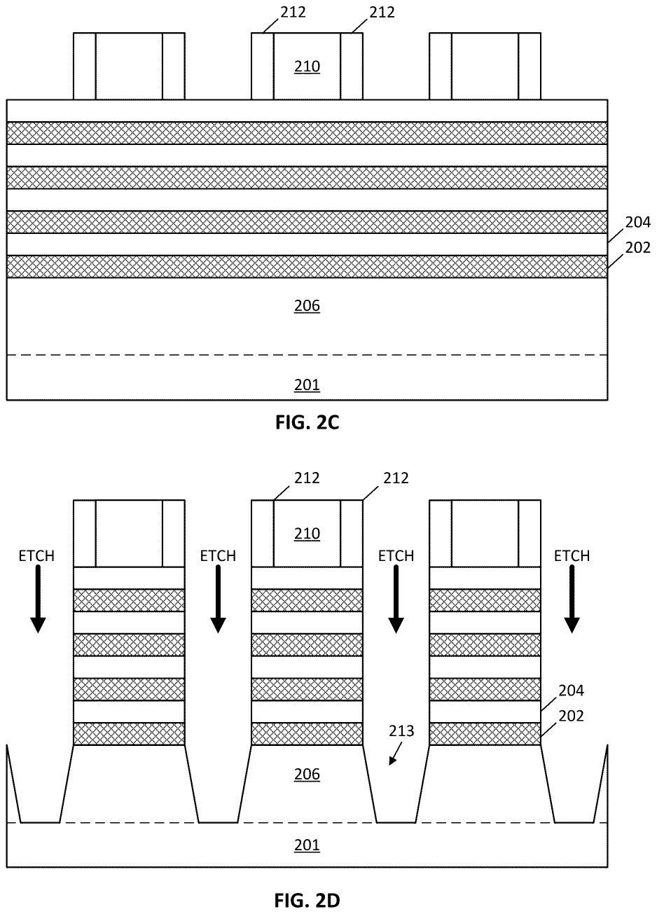

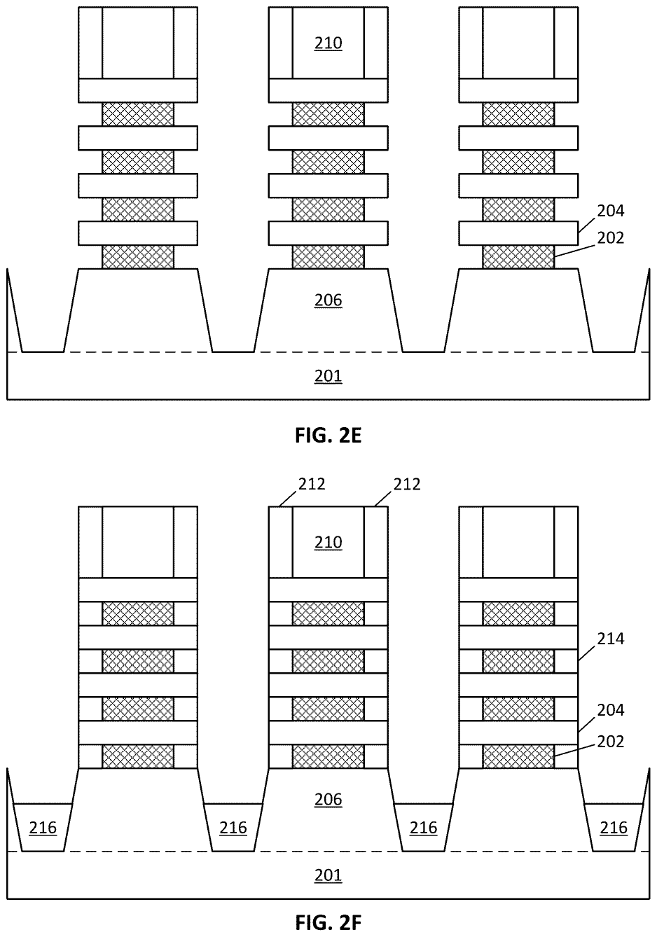

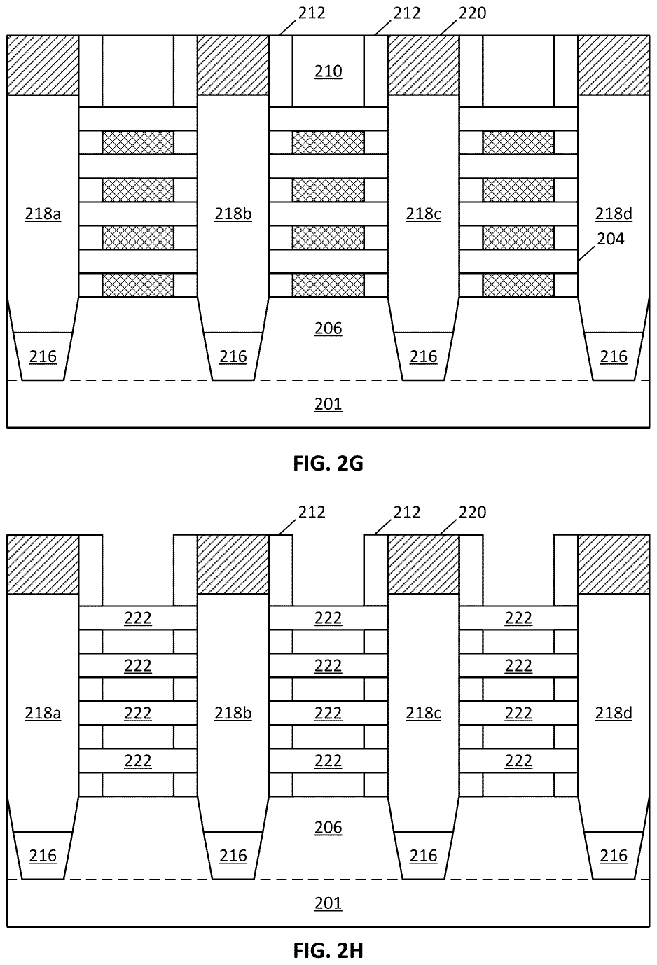

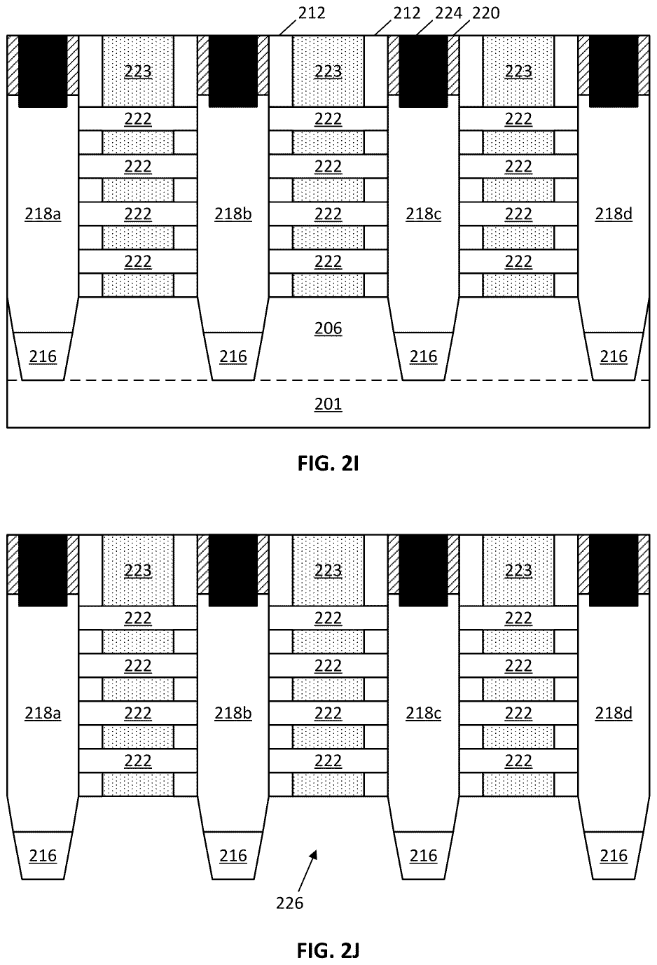

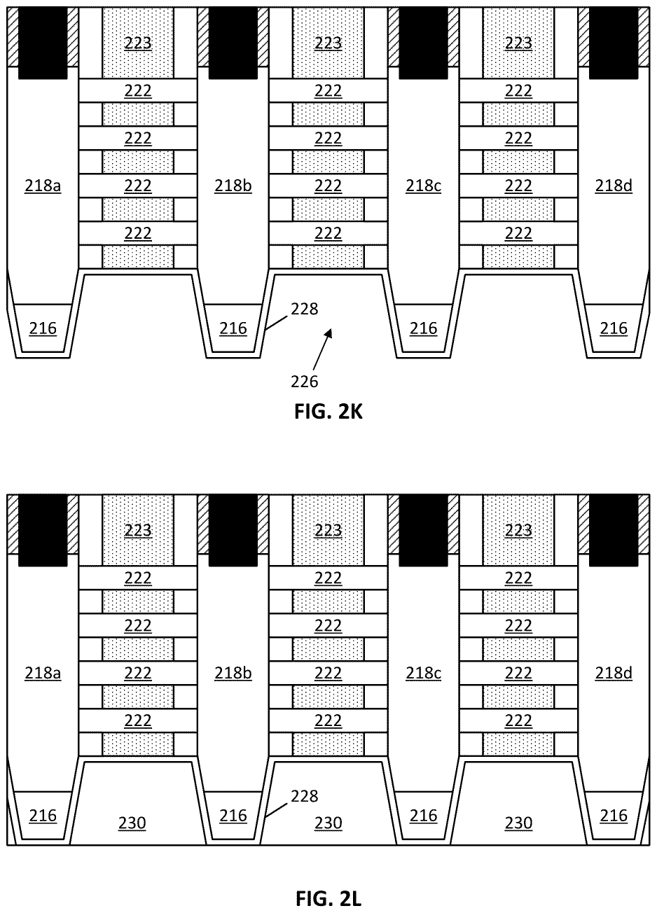

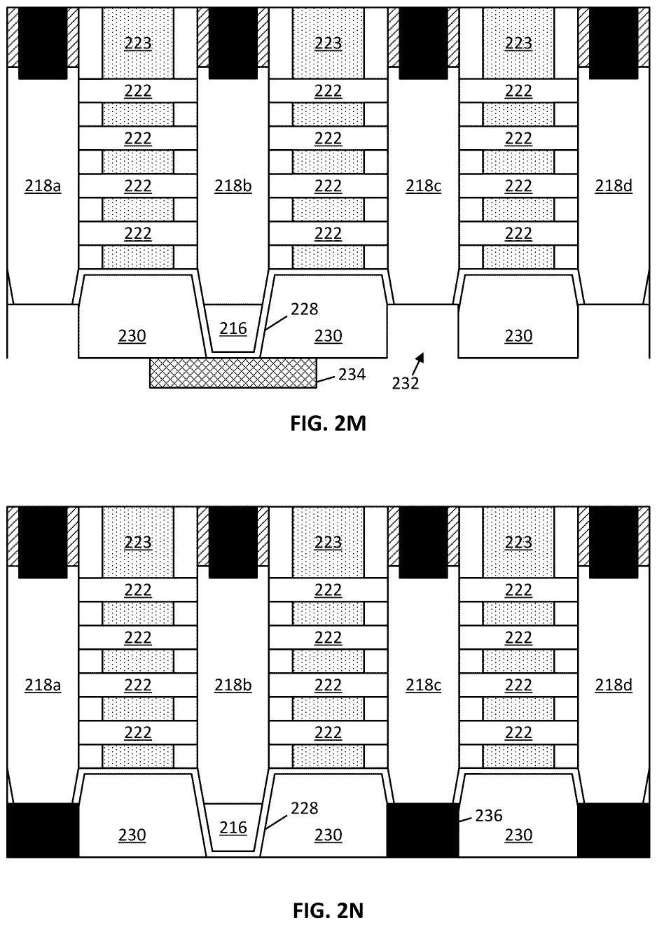

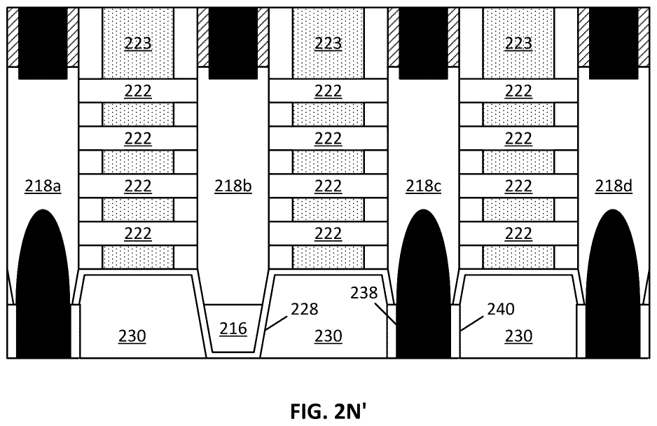

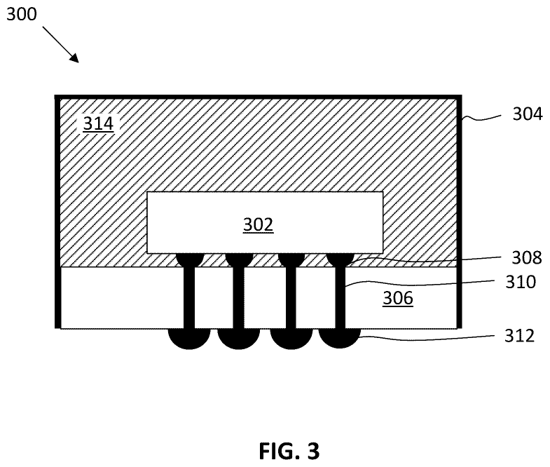

FIGS. 2A-2N include cross-sectional views that collectively illustrate an example process for forming an integrated circuit configured with self-aligned backside contacts, in accordance with an embodiment of the present disclosure. FIGS. 2A-2N represent a similar cross-sectional view as that of FIG. 1 across a series of semiconductor devices. The depicted structure evolves as the process flow continues, culminating in the structure shown in FIG. 2N, which is similar to the structure shown in FIG. 1. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure.

FIG. 2A illustrates a cross-sectional view taken through a substrate 201 having a series of material layers formed over substrate 201, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

FIG. 2B depicts a cross-section view of the structure shown in FIG. 2A following the formation of a cap layer 205 and the subsequent formation of fins beneath cap layer 205, according to an embodiment. Cap layer 205 may be any suitable hard mask material such as a carbon hard mask (CHM) or silicon nitride. Cap layer 205 is patterned into rows to form corresponding rows of fins from the alternating layer stack of sacrificial layers 202 and semiconductor layers 204. Cap layer 205 extends along the top of each fin in a first direction.

According to some embodiments, an anisotropic etching process through the layer stack continues into at least a portion of substrate 201. Portions of substrate 201 beneath the fins are not etched and yield subfin regions 206. The etched portions of substrate 201 that are not under the fins may be filled with a dielectric fill that acts as shallow trench isolation (STI) between adjacent fins. The dielectric fill is not shown in these cross-sections as it extends in the first direction along the sides of subfin regions 206 that are into and out of the page. The dielectric fill may be any suitable dielectric material such as silicon dioxide. The subfin regions 206 represent remaining portions of substrate 201 flanked by the dielectric fill, according to some embodiments.

FIG. 2C depicts a cross-section view of the structure shown in FIG. 2B following the formation of sacrificial gates 210 and spacer structures 212, according to some embodiments. A gate masking layer may first be patterned in strips that extend orthogonally across each of the fins (e.g., in a second direction) in order to form corresponding sacrificial gates 210 in strips beneath the gate masking layers. Afterwards, the gate masking layers may be removed or may remain as a cap layer above each sacrificial gate 210. According to some embodiments, the sacrificial gate material is removed in all areas not protected by the gate masking layers. Sacrificial gate 210 may be any suitable material that can be selectively removed without damaging the semiconductor material of the fins. In some examples, sacrificial gate 210 includes polysilicon.

According to some embodiments, spacer structures 212 are formed along the sidewalls of sacrificial gates 210. Spacer structures 212 may be conformally deposited (e.g., using CVD or ALD) and then etched back or otherwise removed (e.g., via anisotropic or directional etch) from horizontal surfaces, such that spacer structures 212 remain mostly only on sidewalls of any exposed structures. The width of spacer structures 212 (along the first direction) may vary from one example to the next, but in some cases is in the range of 3 nm to 20 nm. According to some embodiments, spacer structures 212 may be any suitable dielectric material, such as silicon nitride, silicon carbon nitride, or silicon oxycarbonitride. In one such embodiment, spacer structures 212 comprise a nitride and the dielectric fill adjacent to subfin regions 206 comprises an oxide, so as to provide a degree of etch selectivity during final gate processing.

FIG. 2D depicts a cross-section view of the structure shown in FIG. 2C following the removal of exposed portions of the fins not protected by sacrificial gates 210 and spacer structures 212, according to some embodiments. The exposed fin portions may be removed using any anisotropic etching process, such as RIE or other directional etch process. The removal of the exposed fin portions creates source/drain trenches that alternate with gate trenches (currently filled with sacrificial gates 210) along the first direction, according to some embodiments. In some embodiments, at least a portion of subfin regions 206 is also removed such that a top surface of subfin regions 206 is recessed below a top surface of the adjacent dielectric fill. In some embodiments, subfin regions 206 within the source/drain trenches are removed entirely (as illustrated), to yield subfin cavities 213. Note that due to the deep etching process, the source/drain trenches may exhibit a tapering width as they extend deeper. Accordingly, at least subfin cavities 213 may have a tapering width, as illustrated.

FIG. 2E depicts a cross-section view of the structure shown in FIG. 2D following the removal of portions of sacrificial layers 202, according to an embodiment of the present disclosure. An isotropic etching process may be used to selectively recess the exposed ends of each sacrificial layer 202 (e.g., while etching comparatively little of semiconductor layers 204).

FIG. 2F depicts a cross-section view of the structure shown in FIG. 2E following the formation of internal spacers 214, according to an embodiment of the present disclosure. Internal spacers 214 may have a material composition that is similar to or the exact same as spacer structures 212. Accordingly, internal spacers 214 may be any suitable dielectric material that exhibits high etch selectively to semiconductor materials such as silicon and/or silicon germanium. Internal spacers 214 may be, for example, conformally deposited over the sides of the fin structure using a conformal deposition process like CVD or ALD and then etched back using an isotropic etching process to expose the ends of semiconductor layers 204. According to some embodiments, internal spacers 214 have a similar width (e.g., along the first direction) to spacer structures 212. According to some embodiments, a portion of the dielectric material used for form internal spacers 214 remains at the bottom of the source/gate trenches as one or more dielectric caps 216. Accordingly, each of dielectric caps 216 may have the same material composition as internal spacers 214. Dielectric caps 216 may fill a portion of subfin cavities 213 and may exhibit the same tapering width profile as subfin cavities 213.

FIG. 2G depicts a cross-section view of the structure shown in FIG. 2F following the formation of source or drain regions 218a-218d (collectively referred to as source or drain regions 218) within the source/drain trenches, according to some embodiments. Source or drain regions 218 may be formed in the areas that had been previously occupied by the exposed fins between spacer structures 212. According to some embodiments, source or drain regions 218 are epitaxially grown from the exposed semiconductor material at the ends of semiconductor layers 204. Note that lower portions of source or drain regions 218 may also be grown from the exposed sidewalls surfaces of subfin region 206. According to some embodiments, source or drain regions 218 are formed directly over dielectric caps 216, such that dielectric caps 216 contact the bottom surfaces of source or drain regions 218.

According to some embodiments, a dielectric fill 220 is provided over source or drain regions 218. In some examples, dielectric fill 220 occupies a remaining volume within the source/drain trenches around and over portions of source or drain regions 218. Dielectric fill 220 may be any suitable dielectric material, such as silicon dioxide. In some examples, dielectric fill 220 extends up to and planar with a top surface of spacer structures 212 (e.g., following a polishing procedure).

FIG. 2H depicts a cross-section view of the structure shown in FIG. 2G following the removal of sacrificial gates 210 and sacrificial layers 202, according to some embodiments. In examples where gate masking layers are still present, they may be removed at this time. Once sacrificial gates 210 are removed, the remaining fin portions extending between spacer structures 212 are exposed.

In the example where the fins include alternating sacrificial layers 202 and semiconductor layers 204, sacrificial layers 202 are selectively removed to leave behind nanoribbons 222 extending between corresponding source or drain regions 218. Each vertical set of nanoribbons 222 represents the semiconductor region (also called channel region) of a different semiconductor device. It should be understood that any of nanoribbons 222 may also be nanowires or nanosheets. Sacrificial gates 210 and sacrificial layers 202 may be removed using the same isotropic etching process or different isotropic etching processes.

FIG. 2I depicts a cross-section view of the structure shown in FIG. 2H following the formation of gate structures 223 around the suspended nanoribbons 222, according to an embodiment of the present disclosure. As noted above, each gate structure 223 includes a gate dielectric and a gate electrode.

The gate dielectric may be conformally deposited around nanoribbons 222 using any suitable deposition process, such as ALD. The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric may include one or more silicates (e.g., titanium silicate, tungsten silicate, niobium silicate, and silicates of other transition metals). The gate dielectric may be a multilayer structure, in some examples. For instance, the gate dielectric may include a first layer on the nanoribbons, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-k material can be nitridized to improve its aging resistance.

The gate electrode may be deposited over the gate dielectric and can be any standard or proprietary conductive material that may include any number of gate cuts. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. P-type workfunction layers include, for example, titanium nitride, and n-type workfunction layers include, for example, tungsten or titanium aluminum carbide.

According to some embodiments, frontside contacts 224 may be formed through dielectric fill 220 to contact the top surfaces of source or drain regions 218. Frontside contacts 224 may include any suitable conductive material, such as tungsten, cobalt, molybdenum, or ruthenium, for making electrical contact with the underlying source or drain regions 218. Although not illustrated, any number of frontside interconnect layers may be formed over the semiconductor devices. The interconnect layers include dielectric layers, conductive vias, and conductive layers to carry power and/or signals to various transistor elements.

FIG. 2J depicts a cross-section view of the structure shown in FIG. 2I following the removal of substrate 201. Any number of polishing, grinding, or etching processes may be used to remove the bulk portion of substrate 201. According to some embodiments, substrate 201 is removed until a bottom surface of dielectric caps 216 and/or a bottom surface of the dielectric fill adjacent to subfin regions 206 are exposed. The backside exposed subfin regions 206 may then be etched away using any suitable isotropic etching process. According to some embodiments, the removal of subfin regions 206 yields backside recesses 226 between portions of source or drain regions 218 with dielectric caps 216 at their tips extending downward away from the bottom surface of gate structures 223.

FIG. 2K depicts a cross-section view of the structure shown in FIG. 2J following the formation of a dielectric liner 228 along any exposed surfaces on the backside of the structure, according to some embodiments. Dielectric liner 228 may include any suitable dielectric material, such as silicon nitride or silicon oxynitride. In some examples, dielectric liner 228 includes the same dielectric material as dielectric caps 216. Dielectric liner 228 may be conformally deposited on the outside surfaces of dielectric caps 216 and on the bottom surfaces of gate structures 223. In some examples, dielectric liner 228 is deposited onto sidewall surfaces of a lower portion of source or drain regions 218 (e.g., any portion extending below the bottom surface of gate structures 223). Accordingly, dielectric liner 228 may extend continuously across an interface between dielectric caps 216 and source or drain regions 218. Dielectric liner 228 may be deposited using any suitable conformal deposition technique, such as CVD or ALD, to a thickness between, for instance, about 2 nm and about 7 nm.

FIG. 2L depicts a cross-section view of the structure shown in FIG. 2K following the formation of a base dielectric structure 230 within backside recesses 226, according to some embodiments. One or dielectric materials may be deposited to form base dielectric structure 230. Furthermore, base dielectric structure 230 may also include the dielectric fill adjacent to backside recesses 226 into and out of the page. Base dielectric structure 230 may include any suitable dielectric material, such as silicon dioxide. According to some embodiments, a bottom surface of base dielectric structure 230 may be polished until a bottom surface of dielectric liner 228 or a bottom surface of dielectric caps 216 is exposed.

FIG. 2M depicts a cross-section view of the structure shown in FIG. 2L following the removal of the dielectric structures at the ends of any number of source or drain regions 218 to form backside cavities 232, according to some embodiments. An isotropic etching process may be used to remove the exposed dielectric caps 216 and exposed portions of dielectric liner 228 from the backside of the structure. In some examples, the angled edges of base dielectric structure 230 may be smoothed over during the etching process, leading to a wider opening for backside cavities 232 that may not strictly follow the tapered profile of dielectric caps 216. According to some embodiments, each backside cavity 232 is self-aligned beneath its corresponding source or drain region 218.

According to some embodiments, a mask structure 234 may be lithographically formed beneath one or more source or drain regions to maintain the dielectric structures beneath those regions and not form a backside contact beneath them. In the illustrated example, a single isotropic etching process removes the dielectric structures beneath first source or drain region 218a, third source or drain region 218c, and fourth source or drain region 218d, while the dielectric structure beneath second source or drain region 218b is protected by mask structure 234. Mask structure 234 may be any suitable hard mask material, such as a dielectric material or carbon hard mask (CHM).

FIG. 2N depicts a cross-section view of the structure shown in FIG. 2M following the formation of backside contacts 236 within backside cavities 232, according to some embodiments. Backside contacts 236 may include any suitable conductive material, such as any of tungsten, ruthenium, molybdenum, or cobalt. Since backside cavities 232 were self-aligned beneath the corresponding source or drain regions 218, backside contacts 236 are respectively self-aligned with their corresponding source or drain regions 218, according to some embodiments. For example, a center of backside contacts 236 may be aligned within 1 nm of a center of source or drain regions 218.

According to some embodiments, the backside contacts may be designed to extend into a portion of the corresponding source or drain regions 218 to provide an enhanced ohmic contact. FIG. 2N′ illustrates another example for forming backside contacts 238 within backside cavities 232 that extend into at least a portion of source or drain regions 218, according to some embodiments. The portion of backside contacts 238 that extend through source or drain regions 218 has an elongated oval shape with a domed, pointed, or flat end. In some examples, this portion of backside contacts 238 extends through at least 30%, at least 40%, at least 50%, or at least 60% of an entire height (e.g., along the Z direction) of source or drain regions 218.

Prior to depositing the conductive material to form backside contacts 238, a second dielectric liner 240 may be deposited within backside cavities 232, according to some embodiments. Second dielectric liner 240 may be formed such that is covers the sidewalls of backside cavities 232 and the exposed bottom surfaces of source or drain regions 218. A directional etching process (e.g., RIE) may be used to punch through a portion of second dielectric liner 240 on the bottom surface of source or drain regions 218. The etch process may continue into the source or drain regions 218 to form recesses to be filled by the conductive material of backside contacts 238. Second dielectric liner 240 may be any suitable dielectric material, such as silicon nitride or titanium nitride, and may have a thickness, for instance, between about 1 nm and about 3 nm.

FIG. 3 illustrates an example embodiment of a chip package 300, in accordance with an embodiment of the present disclosure. As can be seen, chip package 300 includes one or more dies 302. One or more dies 302 may include at least one integrated circuit having semiconductor devices, such as any of the semiconductor devices disclosed herein. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

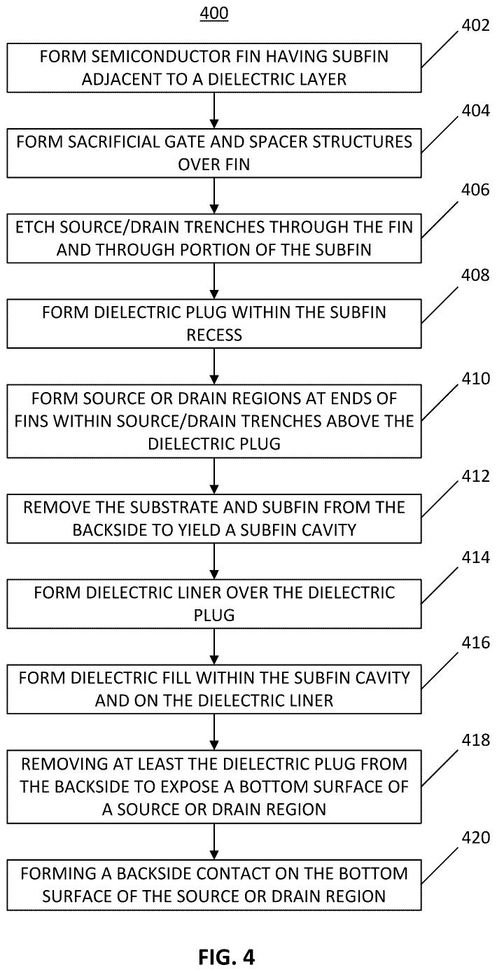

FIG. 4 is a flow chart of a method 400 for forming at least a portion of an integrated circuit, according to an embodiment. Various operations of method 400 may be illustrated in FIGS. 2A-2N. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. For example, method 400 does not explicitly describe various standard processes that are usually performed to form transistor structures. Some of the operations of method 400 may be performed in a different order than the illustrated order.

Method 400 begins with operation 402 where at least one semiconductor fin is formed, according to some embodiments. The semiconductor material in the fin may be formed from a substrate such that the fin is an integral part of the substrate (e.g., etched from a bulk silicon substrate). Alternatively, the fin can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fin includes alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches. The fin may also include a cap structure over its top surface that is used to define the location of the fin during, for example, an RIE process. The cap structure may be a dielectric material, such as silicon nitride.

According to some embodiments, a dielectric layer is formed around a subfin portion of the fin. In some examples, the anisotropic etching process used to from the fin continues into at least a portion of the underlying substrate. The etched portions of the substrate that are not under any fins may be filled with a dielectric fill to form the dielectric layer that acts as STI between adjacent fins. The dielectric layer may be any suitable dielectric material such as silicon dioxide. The subfin represents a remaining portion of the substrate flanked by the dielectric layer beneath the fin, according to some embodiments.

Method 400 continues with operation 404 where a sacrificial gate is formed over the fin. Any number of sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 400 continues with operation 406 where portions of the fin adjacent to the sacrificial gate and spacer structures (e.g., not covered by the sacrificial gate and spacer structures) are removed. Any exposed portions of the fin not covered by the sacrificial gate or spacer structures may be removed using any anisotropic etching process, such as RIE. According to some embodiments, the etch continues past the height of the fin into the subfin such that a recess is etched into the subfin (and possibly further into the bulk substrate) adjacent to the remaining portion of the fin.

Method 400 continues with operation 408, where a dielectric plug is formed within the bottom of the recess. According to some embodiments, the dielectric plug includes the same dielectric material used to form internal spacers between semiconductor layers of the fin. The dielectric plug may fill a bottom portion of the recess etched into the subfin and does not extend above a top surface of the subfin, according to some embodiments. The dielectric plug may be any suitable dielectric material, such as silicon nitride or silicon oxynitride.

Method 400 continues with operation 410 where source or drain regions are formed at the exposed ends of the fin. The source or drain regions may be formed in the areas that had been previously occupied by the exposed fin between the spacer structures. According to some embodiments, the source or drain regions are epitaxially grown from the exposed semiconductor material of the fin (or nanoribbons, nanowires or nanosheets, as the case may be) along the exterior walls of the spacer structures. A dielectric fill may formed between and over the source or drain regions along a given source/drain trench. The dielectric fill may be any suitable dielectric material, such as silicon dioxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth. According to some embodiments, a given source or drain region is grown directly over the dielectric plug, such that a bottom surface of the given source or drain region may contact a top surface of the dielectric plug. Following the formation of the source or drain regions, the sacrificial gate may be removed and replaced with a gate structure.

Method 400 continues with operation 412 where the substrate and subfin are removed from the backside of the structure. The substrate may be removed via any combination of grinding, polishing, and/or etching processes. In some embodiments, the substrate is thinned away at least until a bottom surface of the dielectric plug is exposed. In some examples, the only portions of the semiconductor material from the substrate left behind following the backside polishing process are the subfins. According to some embodiments, the subfins may be removed via a suitable isotropic etching process. Removing the subfin leaves behind a subfin cavity adjacent to the dielectric plug that extends downwards beneath the bottom surface of the gate structure.

Method 400 continues with operation 414 where a dielectric liner is formed over the exposed dielectric plug on the backside of the structure. The dielectric liner may include any suitable dielectric material, such as silicon nitride or silicon oxynitride. In some examples, the dielectric liner includes the same dielectric material as the dielectric plug. According to some embodiments, the dielectric liner is conformally deposited on the outside surface of the dielectric plug using any suitable conformal deposition technique, such as CVD, PECVD, or ALD. In some examples, the dielectric liner is also deposited onto sidewall surfaces of a lower portion of the source or drain region above the dielectric plug such that the dielectric liner extends continuously across an interface between the dielectric plug and the source or drain region.

Method 400 continues with operation 416 where a dielectric fill is formed within the subfin cavity and on the dielectric liner. According to some embodiments, the dielectric fill may be part of a base dielectric structure that also includes the dielectric layer adjacent to the subfin cavity. Accordingly, the dielectric fill may be the same dielectric material as the dielectric layer, such as silicon dioxide. In some examples, a bottom surface of the dielectric fill is polished until at least a bottom surface of the dielectric liner or dielectric plug beneath the source or drain region is exposed.

Method 400 continues with operation 418 where at least the dielectric plug is removed from the backside to expose a bottom surface of the source or drain region. According to some embodiments, an isotropic etching process may be used to selectively remove the dielectric material of the dielectric plug to form a self-aligned backside cavity directly beneath the source or drain region. In some examples, the dielectric liner is isotropically removed as well using the same etching process that removes the dielectric plug, or using a different etching process. Removing the dielectric liner expands the size of the backside cavity, which can make the formation of the backside contacts easier.

Method 400 continues with operation 420 where a backside contact is formed within the backside cavity and on the bottom surface of the source or drain region. The backside contact may include any suitable conductive material, such as any of tungsten, ruthenium, molybdenum, or cobalt. Since the backside cavity was self-aligned beneath the source or drain region, the backside contact is respectively self-aligned beneath the source or drain region, according to some embodiments. In some examples, a directional etching process is used prior to the deposition of any conductive material to etch a recess into the backside of the source or drain region. The conductive material is subsequently deposited within both the backside cavity and the recess to form a backside contact that extends into the backside of the source or drain region.

### Example System

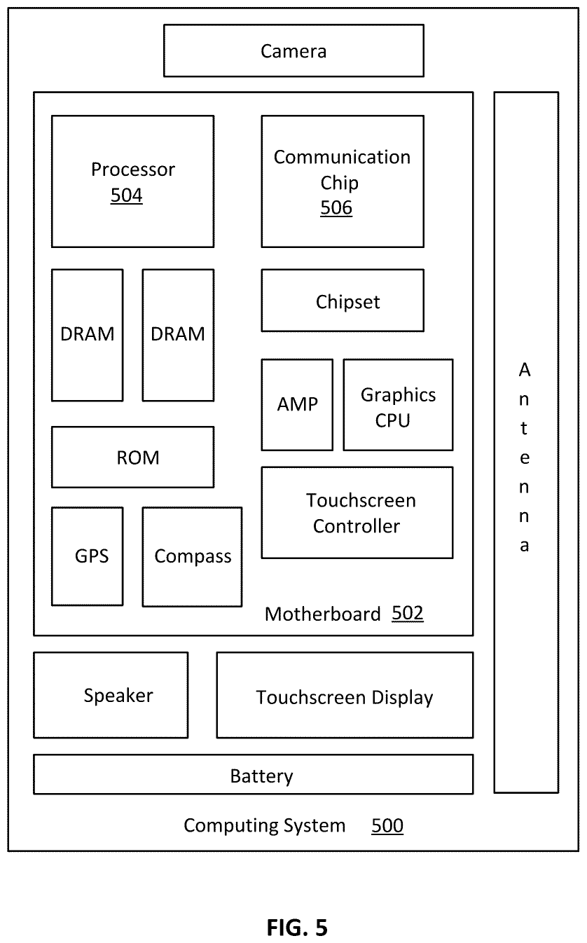

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment (e.g., a module including an integrated circuit configured with self-aligned backside contacts, as variously provided herein). In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a semiconductor region extending in a first direction from a first source or drain region to a second source or drain region and a gate structure extending in a second direction over the semiconductor region, a dielectric layer beneath the gate structure, a backside conductive contact extending through the dielectric layer and contacting a bottom surface of the first source or drain region, and a dielectric structure extending through the dielectric layer and contacting a bottom surface of the second source or drain region. The dielectric structure includes a dielectric cap and a dielectric liner on an outer surface of the dielectric cap.

Example 2 includes the integrated circuit of Example 1, wherein the dielectric cap has a different material composition compared to the base dielectric structure.

Example 3 includes the integrated circuit of Example 1 or 2, wherein the dielectric cap comprises silicon, oxygen, and nitrogen.

Example 4 includes the integrated circuit of Example 3, wherein the dielectric liner comprises silicon and nitrogen.

Example 5 includes the integrated circuit of any one of Examples 1-4, wherein the dielectric liner contacts at least a portion of the first source or drain region.

Example 6 includes the integrated circuit of Example 5, wherein the dielectric liner extends continuously across an interface between the dielectric cap and the first source or drain region.

Example 7 includes the integrated circuit of any one of Examples 1-6, wherein the dielectric liner contacts at least a portion of the second source or drain region.

Example 8 includes the integrated circuit of any one of Examples 1-7, wherein the semiconductor region comprises a plurality of semiconductor nanoribbons or nanosheets.

Example 9 includes the integrated circuit of Example 8, wherein the plurality of semiconductor nanoribbons or nanosheets comprise germanium, silicon, or a combination thereof.

Example 10 is a die that includes the integrated circuit of any one of Examples 1-9.

Example 11 is an electronic device having a chip package with one or more dies. At least one of the one or more dies includes a semiconductor region extending in a first direction from a first source or drain region to a second source or drain region, a gate structure extending in a second direction over the semiconductor region, a base dielectric structure beneath the gate structure, a conductive contact extending through the base dielectric structure and contacting a bottom surface of the first source or drain region, a dielectric structure extending through the base dielectric structure and contacting a bottom surface of the second source or drain region. The dielectric structure includes a dielectric cap and a dielectric liner on an outer surface of the dielectric cap.

Example 12 includes the electronic device of Example 11, wherein the dielectric cap has a different material composition compared to the base dielectric structure.

Example 13 includes the electronic device of Example 11 or 12, wherein the dielectric cap comprises silicon, oxygen, and nitrogen.

Example 14 includes the electronic device of Example 13, wherein the dielectric liner comprises silicon and nitrogen.

Example 15 includes the electronic device of any one of Examples 11-14, wherein the dielectric liner contacts at least a portion of the first source or drain region.

Example 16 includes the electronic device of Example 15, wherein the dielectric liner extends continuously across an interface between the dielectric cap and the first source or drain region.

Example 17 includes the electronic device of any one of Examples 11-16, wherein the dielectric liner contacts at least a portion of the second source or drain region.

Example 18 includes the electronic device of any one of Examples 11-17, wherein the semiconductor region comprises a plurality of semiconductor nanoribbons or nanosheets.

Example 19 includes the electronic device of Example 18, wherein the plurality of semiconductor nanoribbons or nanosheets comprise germanium, silicon, or a combination thereof.

Example 20 includes the electronic device of any one of Examples 11-19, further comprising a printed circuit board, wherein the chip package is coupled to the printed circuit board.

Example 21 is a method of forming an integrated circuit. The method includes: forming a fin comprising semiconductor material, the fin extending above a substrate; forming a dielectric layer adjacent to a subfin of the fin; forming a sacrificial gate and spacer structures over the fin; removing portions of the fin not covered by the sacrificial gates and spacer structures; removing a portion of the subfin to form a subfin recess; forming a first dielectric material within the subfin recess; forming a source or drain region at exposed ends of the semiconductor material above the first dielectric material; removing the subfin to yield a cavity adjacent to a bottom portion of the source or drain region; forming a dielectric liner on the exposed surfaces of the first dielectric material; forming a second dielectric material within the cavity and over the dielectric liner; polishing a backside surface of the second dielectric material to expose a bottom surface of the first dielectric material; removing at least the first dielectric material from the backside to expose a bottom surface of the source or drain region; and forming a conductive contact on the exposed bottom surface of the source or drain region.

Example 22 includes the method of Example 21, wherein forming the first dielectric material comprises forming a material comprising oxygen, nitrogen, and silicon.

Example 23 includes the method of Example 21 or 22, wherein forming the dielectric liner comprises forming a material comprising nitrogen and silicon.

Example 24 includes the method of any one of Examples 21-23, wherein forming the dielectric liner comprises forming the dielectric liner on exposed surfaces of the source or drain region.

Example 25 includes the method of any one of Examples 21-24, wherein the cavity extends between the source or drain region and a second source or drain region.

Example 26 is an integrated circuit that includes a first semiconductor device having a first semiconductor region extending in a first direction from a first source or drain region to a second source or drain region and a first gate structure extending in a second direction over the first semiconductor region, a second semiconductor device having a second semiconductor region extending in the first direction from a third source or drain region to a fourth source or drain region and a second gate structure extending in the second direction over the second semiconductor region, a dielectric layer beneath the first gate structure and the second gate structure, a conductive contact extending through the dielectric layer and contacting a bottom surface of the first source or drain region, and a dielectric structure extending through the dielectric layer and contacting a bottom surface of the third source or drain region. The dielectric structure includes a dielectric cap and a dielectric liner on an outer surface of the dielectric cap.

Example 27 includes the integrated circuit of Example 26, wherein the dielectric cap has a different material composition compared to the base dielectric structure.

Example 28 includes the integrated circuit of Example 26 or 27, wherein the dielectric cap comprises silicon, oxygen, and nitrogen.

Example 29 includes the integrated circuit of Example 28, wherein the dielectric liner comprises silicon and nitrogen.

Example 30 includes the integrated circuit of any one of Examples 26-29, wherein the dielectric liner contacts at least a portion of the first source or drain region.

Example 31 includes the integrated circuit of Example 30, wherein the dielectric liner extends continuously across an interface between the dielectric cap and the first source or drain region.

Example 32 includes the integrated circuit of any one of Examples 26-31, wherein the dielectric liner contacts at least a portion of the third source or drain region.

Example 33 includes the integrated circuit of any one of Examples 26-32, wherein the first semiconductor region comprises a first plurality of semiconductor nanoribbons or nanosheets, and the second semiconductor region comprises a second plurality of semiconductor nanoribbons or nanosheets.

Example 34 includes the integrated circuit of Example 33, wherein the first plurality of semiconductor nanoribbons or nanosheets and the second plurality of semiconductor nanoribbons or nanosheets comprise germanium, silicon, or a combination thereof.

Example 35 is a die that includes the integrated circuit of any one of Examples 26-34.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a first source or drain region to a second source or drain region, and a gate structure extending in a second direction over the semiconductor region;
a base dielectric structure beneath the gate structure;
a conductive contact extending through the base dielectric structure and contacting a bottom surface of the first source or drain region; and
a dielectric structure extending through the base dielectric structure and contacting a bottom surface of the second source or drain region, wherein the dielectric structure comprises
a dielectric cap, and
a dielectric liner on an outer surface of the dielectric cap.

2. The integrated circuit of claim 1, wherein the dielectric cap has a different material composition compared to the base dielectric structure.

3. The integrated circuit of claim 1, wherein the dielectric cap comprises silicon, oxygen, and nitrogen.

4. The integrated circuit of claim 3, wherein the dielectric liner comprises silicon and nitrogen.

5. The integrated circuit of claim 1, wherein the dielectric liner contacts at least a portion of the first source or drain region.

6. The integrated circuit of claim 5, wherein the dielectric liner extends continuously across an interface between the dielectric cap and the first source or drain region.

7. The integrated circuit of claim 1, wherein the dielectric liner contacts at least a portion of the second source or drain region.

8. A die comprising the integrated circuit of claim 1.

9. An electronic device, comprising:
a chip package comprising one or more dies, at least one of the one or more dies comprising
a semiconductor region extending in a first direction from a first source or drain region to a second source or drain region;
a gate structure extending in a second direction over the semiconductor region;
a base dielectric structure beneath the gate structure;
a conductive contact extending through the base dielectric structure and contacting a bottom surface of the first source or drain region; and
a dielectric structure extending through the base dielectric structure and contacting a bottom surface of the second source or drain region, wherein the dielectric structure comprises
a dielectric cap, and
a dielectric liner on an outer surface of the dielectric cap.

10. The electronic device of claim 9, wherein the dielectric cap has a different material composition compared to the base dielectric structure.

11. The electronic device of claim 9, wherein the dielectric liner contacts at least a portion of the first source or drain region.

12. The electronic device of claim 11, wherein the dielectric liner extends continuously across an interface between the dielectric cap and the first source or drain region.

13. The electronic device of claim 9, wherein the dielectric liner contacts at least a portion of the second source or drain region.

14. An integrated circuit comprising:
a first semiconductor device having a first semiconductor region extending in a first direction from a first source or drain region to a second source or drain region, and a first gate structure extending in a second direction over the first semiconductor region;
a second semiconductor device having a second semiconductor region extending in the first direction from a third source or drain region to a fourth source or drain region, and a second gate structure extending in the second direction over the second semiconductor region;
a base dielectric structure beneath the first gate structure and the second gate structure;
a conductive contact extending through the base dielectric structure and contacting a bottom surface of the first source or drain region; and
a dielectric structure extending through the base dielectric structure and contacting a bottom surface of the third source or drain region, wherein the dielectric structure comprises
a dielectric cap, and
a dielectric liner on an outer surface of the dielectric cap.

15. The integrated circuit of claim 14, wherein the dielectric cap comprises silicon, oxygen, and nitrogen.

16. The integrated circuit of claim 15, wherein the dielectric liner comprises silicon and nitrogen.

17. The integrated circuit of claim 14, wherein the dielectric liner contacts at least a portion of the first source or drain region.

18. The integrated circuit of claim 17, wherein the dielectric liner extends continuously across an interface between the dielectric cap and the first source or drain region.

19. The integrated circuit of claim 14, wherein the dielectric liner contacts at least a portion of the third source or drain region.

20. The integrated circuit of claim 14, wherein the dielectric cap has a different material composition compared to the base dielectric structure.
